(19) United States
(12) Patent Application Publication
(10) Pub. No.: US 2026/0249331 A1
(43) Pub. Date: Aug. 27, 2026

(54) FLUID EVACUATION AND CHEMICAL CLEANING DEVICE

(71) Applicant: Raytheon Company, Arlington, VA (US)

(72) Inventors: Amgad M. Salama, Ontario, CA (US); Arin Navasartian, Tujunga, CA (US); Jonathan Giddens, Anna, TX (US); Jason M. Ritacco, Murphy, TX (US); Nikiea T. Haywood, McKinney, TX (US); Alan V. Truong, Garland, TX (US); William C. Bosworth, McKinney, TX (US)

(21) Appl. No.: 19/065,728

(22) Filed: Feb. 27, 2025

(51) Int. Cl. B08B 9/032; C09K 5/10; C11D 7/26; H05K 7/20

(52) U.S. Cl. CPC B08B 9/0325; B08B 9/0328; C09K 5/10; C11D 7/261; H05K 7/20272

(57) ABSTRACT

A fluid evacuation and chemical cleaning apparatus is provided to drain, clean and replace Polyalphaolefin (PAO) in a system. The apparatus is fully automated and integrates disparate parts in a distinct configuration, featuring a custom graphical user interface (GUI) for operation. The apparatus is capable of flushing the system with isopropyl alcohol (IPA) and drying with compressed dry air, and is housed within a mobile cart containing plumbing, pumps, manifolds, sensors, solenoids, check valves, and control electronics.

### GOVERNMENTAL RIGHTS

This invention was made with government support. The government has certain rights in the invention.

### FIELD

The subject matter disclosed herein relates to structural cooling, and transpiration cooling of an airframe.

### BACKGROUND

The use of oil in various applications, including semiconductor processing and electronic cooling systems, is driven by the ability to effectively manage thermal stresses. In environments where electronic components and systems are subjected to high temperatures, oil serves as a useful medium for heat dissipation. Thermal stresses arise when there is a significant temperature gradient within a material or between different materials, leading to expansion or contraction. This can result in mechanical stress, potentially causing damage or failure of components. Accordingly, oil is circulated to absorb and transfer heat away from sensitive components, reducing the risk of thermal-induced failures. By managing thermal stresses, oil contributes to the longevity and reliability of electronic systems. However, the process of evacuating and refilling the oil in such systems may present significant challenges. The oil is difficult to fully evacuate, which can lead to contamination issues. Contamination may affect the performance and longevity of the electronic components detrimentally. Additionally, incomplete evacuation poses risks during shipping, such as hazardous material (HAZMAT) concerns and potential spillage, which can further complicate logistics and safety protocols.

### BRIEF DESCRIPTION OF THE FIGURES

In the figures, which are not necessarily drawn to scale, like numerals may describe similar components in different views. Like numerals having different letter suffixes may represent different instances of similar components. The figures illustrate generally, by way of example, but not by way of limitation, various embodiments discussed in the present document.

FIGS. 1A-1E show a cart housing components of the automated system.

FIG. 2 illustrates the fluid routing schematic.

FIGS. 3A-3D illustrate the graphical user interface (GUI) during different operations of the automated system.

FIG. 4 shows a flowchart of operations of the automated system.

FIG. 5 shows a table of operations of the automated system.

FIG. 6 illustrates a block diagram of an electronic device in accordance with some embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Current solutions for replacing oil in electronic cooling systems often involve manual processes that are not only labor-intensive but also prone to human error. These methods typically lack the capability to fully automate the evacuation and refilling process, leading to inefficiencies and potential contamination. Moreover, existing systems do not adequately address issues related to thorough cleaning and drying of the components, which can result in premature wear and failure of the hardware as well as complicate transport of the systems if desired. The absence of integrated systems that can effectively manage these tasks highlights a significant gap in the systems.

The subject matter described herein mitigates these issues by introducing a fully automated apparatus for fluid evacuation and chemical cleaning of a connected system utilizing a coolant (e.g., oil) that is to be evacuated and replaced. The automated apparatus integrates various parts in a distinct configuration, featuring a custom user-interface GUI for controlling operations of the automated apparatus. The automated apparatus includes the capability to flush lines in the connected system (as well as the automated apparatus) with a solvent such as isopropyl alcohol (IPA) and dry with compressed air prior to refilling the connected system with new coolant. The automated apparatus may be housed within a mobile cart having self-contained plumbing, pumps, manifolds, sensors, solenoids, check valves, and control electronics, all operated via a user-friendly touch screen interface. This configuration allows for efficient and effective draining, cleaning, and refilling processes as well as removing air bubbles within the new coolant, addressing contamination and maintenance issues associated with liquid cooling systems.

One such oil is Polyalphaolefin (PAO), which is a synthetic hydrocarbon fluid that may be used as a lubricant base oil. PAO is produced through the polymerization of alpha-olefins, which are an unsaturated hydrocarbon. PAOs have several desirable traits, including excellent thermal stability, low volatility, and high viscosity index, making PAOs suitable for use in extreme temperature conditions. These properties make PAOs useful for applications in automotive and industrial lubricants, as well as in cooling systems for electronic devices, where PAOs help to efficiently transfer heat and reduce wear on components. In electronic cooling systems, PAO is circulated to absorb and transfer heat away from sensitive components, reducing the risk of thermal-induced failures. By managing thermal stresses, PAO contributes to the longevity and reliability of electronic systems, making it a useful component in applications where precise temperature control is desirable.

In particular, the PAO characteristics include high oxidation resistance and consistent viscosity over a wide temperature range, and low volatility, each of which may depend on the specific formulation and additives used in the PAO. The PAO may, for example, resist oxidation from low ambient temperatures to about 150° C. to 200° C., which helps prevent the formation of sludge and varnish that can impair the performance of cooling and lubrication systems. The PAO may, over the same temperature range, maintain a relatively stable viscosity that, for example, may in industrial and automotive applications range from about 2 centistokes (cSt) to over 100 cSt at 40° C. Similarly, the PAO has a low evaporation rate, which reduces the loss of fluid at high temperatures. The exact evaporation rate would typically be determined through specific testing and would be provided by the manufacturer for a given PAO product.

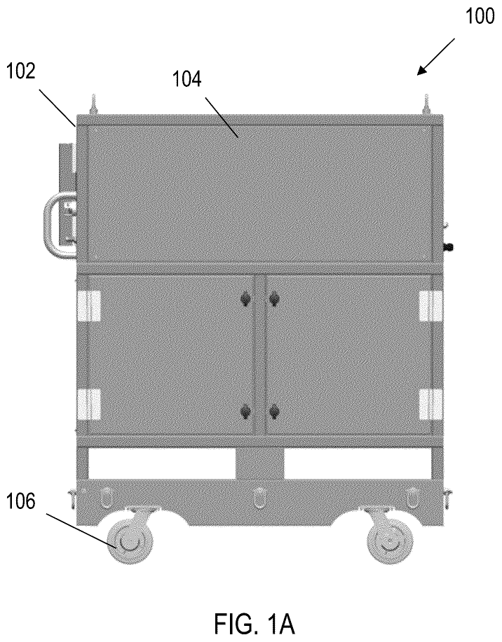

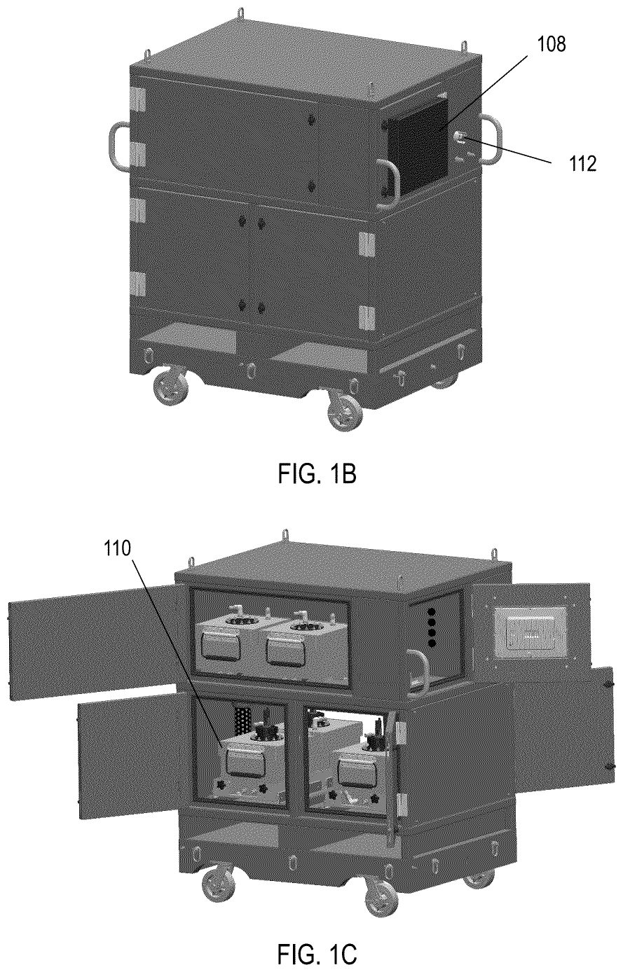

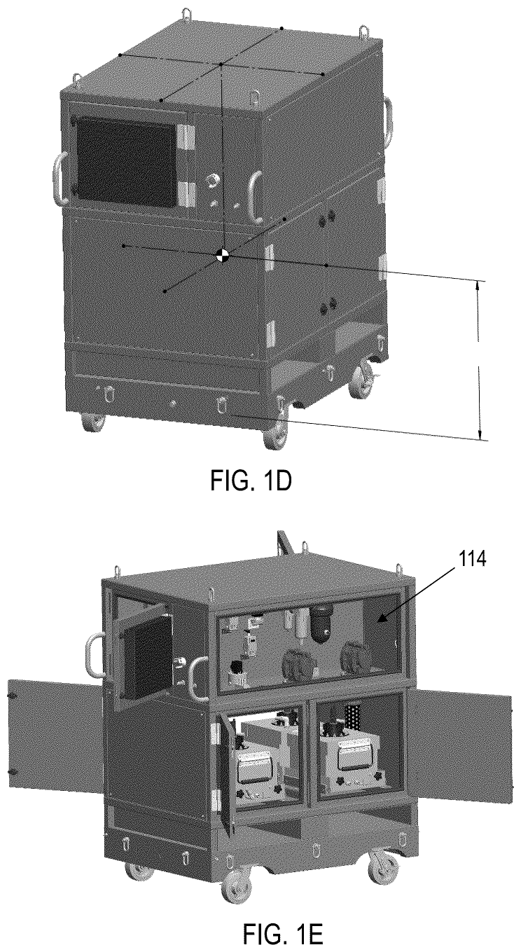

FIGS. 1A-1E show a cart housing components of the automated system. The cart 100 used to house the components of the fluid evacuation and chemical cleaning device is a mobile, self-contained housing designed for ease of use and efficient operation. The cart 100 includes a frame (or housing) 102 made of a material, such as steel, that is sufficient to support integrated plumbing and electronic systems used for the automated processes of draining, cleaning, and refilling electronic units with the coolant (e.g., PAO). The individual reservoirs and tanks used to store liquids are accessible using corresponding cabinets 104 of the cart 100 having hinged doors. The cart 100 is equipped with retractable casters 106, allowing the cart 100 to be transported to different locations to provide maintenance to electronic units to be connected to the device. In some cases, the casters 106 may be retractable (e.g., using a rachet system) for long-distance transport in a vehicle and/or provide additional stability during operation of the device. The casters 106, for example, may be able to be adjusted to rotate so that the axles of the casters 106 is perpendicular to the ground rather than being parallel to the ground when the cart 100 is being moved using the casters 106. The casters 106 may have individual brake pedals that are able to control rotation of each caster 106. The cart 100 may have hoist rings to allow the cart to be mechanically lifted by a hoist, as well as multiple handles on each of opposing sides of the cart 100. The cart 100 features forklift tunnels for maneuverability by forklift.

The cart 100 may also have a GUI 108 (shown in FIG. 1B). The GUI 108 is user-friendly touch screen interface mounted on the cart 100. The GUI 108 may provide operators with a simple and intuitive way to control different functions of the device, provide feedback during each stage of operation, and provide warnings during operation, among others. For example, the GUI 108 may permit the initiation, execution, and termination of various operations, such as draining, IPA flushing, drying with compressed air, and refilling with PAO.

The cart 100 contains a comprehensive plumbing system that facilitates the flow of fluids in and out of the connected electronic unit. This system includes source and waste containers 110 for PAO and IPA (shown in FIG. 1C), ensuring that used fluids are properly collected and new fluids are efficiently delivered. The source and waste containers 110 may be safety hazmat controlled containers. In some cases, multiple source and waste containers 110 for each liquid (PAO and IPA) may be present in the cart 100.

Integrated pumps and manifolds, as well as connectors, 114 within the cart 100 manage the movement and distribution of fluids. These components maintain the correct flow rates and pressures for effective cleaning and refilling.

The cart 100 is equipped with sensors, such as flowmeters and pressure transducers, to monitor the performance and ensure optimal operation. Control electronics manage the processes, providing real-time feedback and adjustments as desired, which may be displayed on the GUI 108.

Check valves and solenoid valves are disposed within the plumbing system to control the direction and flow of fluids. These components prevent backflow and ensure that fluids are directed to the appropriate waste or supply containers 110.

A built-in compressed dry air system in the cart 100 is used to dry the electronic units after IPA flushing, ensuring that no residual moisture remains before refilling with PAO.

The cart 100 may have a large red emergency “STOP” button 112 that is quickly and easily accessible, adjacent to the GUI 108 and/or on the GUI 108. The emergency button 112 halts automated operations. Manual activation of the emergency button 112 disables power to all input and output devices. To restart operation and recover from an emergency condition after the activation of the emergency button 112, the emergency button 112 may be twisted and pulled out or depressed in different implementations.

The cart 100 has a control system that is controlled via the GUI 108. The GUI 108 is able to control starting, executing, and stopping the individual fill/flush operations described herein. The GUI 108 also monitors (via the sensors) and displays volumetric flowrates readings and pressure readings, indicates the IPA/PAO waste containers'filling level (and notification upon maximum fill), and shows various types of alerts/errors in the cart 100 (for example: a pop-up window about clogged air, IPA, PAO hoses/pipes, etc.), and instructions to remedy alerts/errors. The GUI 108 is also able to retrieve a log of past operations (e.g., 10, dependent on an amount of memory associated with the GUI 108) with timestamps of performed individual fill/flush operations and any alerts/errors, restart the control system in case of an error that has occurred, indicate the operation status (percentage of completion) for each operation, and control adjustment of the fluid flow rate (given variation of atmosphere temperature and fluid viscosity) and relieve pressure (when safe) due to an error, upon user request.

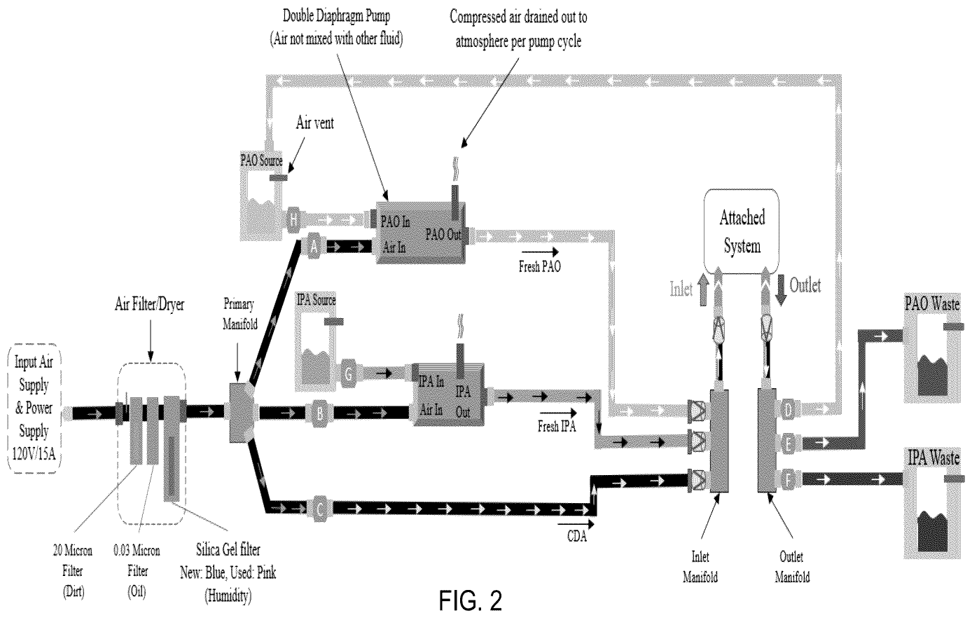

FIG. 2 illustrates the fluid routing schematic of the automated system. The automated system may have both air and power inputs that respectively supply compressed air and power to the cart. Each operation is controlled and completed by the cart automated system, automatically. The cart automated system has four main operations that each consists of one or more stages such as emptying the attached system of coolant (Drain), cleaning and drying the attached system (Flush), and refilling as well as circulating the coolant in the attached system (Fill). The four automated operations are the followings: “Drain” that only completes the draining stage, automatically; “Flush” that only completes the cleaning via IPA as well as drying with compressed dry air, automatically; “Fill” that only completes the filling/ circulating stage, automatically; “Flush/Fill” that completes draining, flushing (cleaning and drying), and filling sequence of stages, automatically. For example, using compressed dry air, old coolant (e.g., PAO as described below, but any coolant may be used) is emptied from attached system to an internal PAO waste container in the cart. Isopropyl alcohol (IPA) is then pumped from internal IPA source container in the cart through the attached system into an internal IPA waste container in the cart. Compressed dry air is then used to dry the attached system and direct any residual mixture of IPA into the internal IPA waste container. New PAO is pumped from an internal PAO source container in the cart to the attached system to fill the attached system. After the attached system gets filled, PAO circulation for a specified time removes air bubbles from the system via the ventilation port featured in the internal PAO source container.

The compressed air may be supplied through tubing in the cart to an air filter and dryer and from there to various pumps and manifolds through check valves and solenoid valves. The filter and dryer is integrated into the cart to ensure delivery of clean, dry compressed air to remove any residual moisture from the compressed air and use the clean, dry compressed air during various operations of the automated system. The air filter portion of the filter and dryer removes particulates and contaminants from the compressed air before the compressed air is used in the drying process. A single air filter or multiple air filters that filter different sized particles may be used. For example, a 20 micron filter may be used to remove dirt and a 0.03 micron filter may be used to remove oil from the air introduced from the compressor or other external source of the compressed air. After filtering the air, the filtered air may be supplied to a desiccant material, such as silica gel, to absorb moisture from the compressed air, ensuring that the air is sufficiently dry to effectively remove any residual moisture from the electronic units. The desiccant may be housed in a transparent container, allowing operators to visually monitor its condition. A change in color of the desiccant changes color indicates saturation and time for replacement.

The automated system further includes sensors to monitor air pressure throughout the lines, ensuring that the correct pressure levels are maintained throughout the different processes, for example drying. This helps to optimize the drying efficiency and prevent any potential damage to the electronic units. The air filter and dryer is integrated with the control system of the cart, allowing operators to monitor and adjust the processes via the GUI.

After having been filtered and dried, the compressed dry air is provided to the primary manifold of the cart, which manages the distribution and flow of fluids throughout the automated system during the various stages of different operations. The primary manifold serves as a central hub that connects different components of the automated system, ensuring that the compressed air is directed efficiently and effectively to the intended destinations. The primary manifold is equipped with solenoid and check valves that control the flow of the compressed dry air. Solenoid valves can be actuated to open or close specific pathways, allowing for precise control over the distribution of the compressed dry air. Check valves ensure one-way flow, preventing any backflow that could compromise the processes.

In particular, different lines connect the primary manifold with downstream components to individually control the supply of the compressed dry air from the primary manifold to the downstream components through individual solenoid valves. The individual solenoid valves may be disposed at any point along the lines connecting the primary manifold and the downstream components and may be individually controlled by the control system. The downstream components include a coolant (PAO) pump, an IPA pump, and the inlet and outlet manifold.

The PAO pump is responsible for the movement and management of PAO during the various stages of operation. The PAO pump is designed to facilitate the transfer of PAO from a PAO source container to the attached system and circulating back to the internal PAO source container in a loop for a specified time period. The pump receives PAO from the internal PAO source container in the cart through a solenoid valve and receives the compressed dry air from the manifold through another solenoid valve. The PAO pump operates by creating a pressure differential that moves the PAO through the plumbing network.

The PAO pump may be, for example, a positive displacement pump such as a double diaphragm pump or a centrifugal pump. The PAO pump operates by creating a pressure differential between the inlet and outlet using the compressed dry air. In a positive displacement pump, this is achieved by trapping a fixed amount of PAO and forcing the PAO through the pump's discharge outlet. A double diaphragm pump is a type of positive displacement pump that uses two flexible diaphragms that reciprocate back and forth to create a pumping action. The PAO double diaphragm pump may be powered by compressed dry air, which is directed by an air valve system to alternately pressurize the chambers behind each diaphragm and includes an air drain mechanism to remove trapped air within the pump. This causes the diaphragms to move in a reciprocating motion. In a centrifugal pump, the impeller's rotation imparts kinetic energy to the PAO, converting the PAO into pressure energy as the fluid moves through the pump. The IPA pump may be a positive displacement pump that is configured to create a pressure differential for moving IPA through the system.

The PAO pump is equipped with check valves at the inlet and outlet ports to control the direction of fluid flow. These valves open and close in response to the movement of the diaphragms, ensuring that fluid is drawn into the pump on the suction side and expelled on the discharge side.

The PAO source container is equipped with a quick connect coupling, allowing for easy connection and disconnection during maintenance or refilling. The PAO is drawn into the PAO pump through this input connection. Once the PAO is pressurized by the PAO pump, the PAO is directed to the attached system for refilling and circulating through the system. The output from the PAO pump is controlled to ensure the correct flow rate and pressure through the lines for the refilling process and ensure the electronic units are adequately serviced. The PAO source container also has an air vent.

The PAO pump includes an air drain mechanism to remove any trapped air within the PAO pump or the fluid lines. This maintains consistent fluid flow and preventing air locks that could disrupt the operation of the automated system. The air drain ensures that the PAO is delivered smoothly and efficiently to its intended destination.

The IPA pump is similar to the PAO pump. The IPA pump is responsible for the movement and management of IPA during the various stages and operations. The IPA pump is designed to facilitate the transfer of IPA from the IPA source container to the attached system and then to the IPA waste container. The pump receives IPA from the internal IPA source container in the cart and the compressed dry air. The IPA pump operates by creating a pressure differential that moves the IPA through the plumbing network.

The IPA pump may be, for example, a positive displacement pump such as a double diaphragm pump or a centrifugal pump. The IPA pump is equipped with check valves at the inlet and outlet ports to control the direction of fluid flow. The IPA pump includes an air drain mechanism to remove any trapped air within the IPA pump or the fluid lines.

The IPA source container is equipped with a quick connect coupling, allowing for easy connection and disconnection during maintenance or refilling. The IPA is drawn into the IPA pump through this input connection. Once the IPA is pressurized by the IPA pump, the IPA is directed to the attached system for cleaning the residual PAO within the attached system. The output from the IPA pump is controlled to ensure the correct flow rate and pressure through the lines. The IPA source container also has an air vent.

The inlet and outlet manifold has an input portion and an output portion and works in conjunction with pressure transducers and flowmeters to monitor and regulate the pressure and flow rate of fluids. The inlet and outlet manifold is integrated with the control electronics, allowing for automated operation and real-time monitoring via the GUI.

The PAO from the PAO pump, the IPA from the IPA pump, and the compressed dry air from the primary manifold are supplied to the inlet and outlet manifold through individual check valves. The inlet and outlet manifold is responsible for directing the flow of PAO, IPA, and compressed dry air to and from the attached system being serviced. The inlet and outlet manifold connects the supply and waste containers, pumps, and other components, facilitating the transfer of fluids. Check valves are installed at the input portion of the inlet and outlet manifold and solenoid valves are installed at the output portion of the inlet and outlet manifold. The solenoid valves can be actuated to open or close specific pathways, while check valves ensure one-way flow, preventing backflow and cross-contamination between different fluids.

After the fluids-PAO, IPA, and compressed dry air-are directed from the inlet manifold to the attached system, the automated system manages the returning fluids by providing the fluids from outlet manifold to the appropriate containers using solenoid valves coupled to check valves, completing the cycle of operation.

For example, PAO in the attached system that is being replaced is supplied from the outlet manifold to the PAO waste container. IPA used to flush the attached system after draining the PAO is supplied from the outlet manifold to the IPA waste container. The PAO and IPA waste containers each have an air vent. After the compressed dry air has been used to dry the attached system, the compressed dry air is vented. In the filling stage/operation after the PAO has been circulated in a loop of the attached system and PAO source container for refilling, any excess PAO is directed through tubing back to the PAO source container.

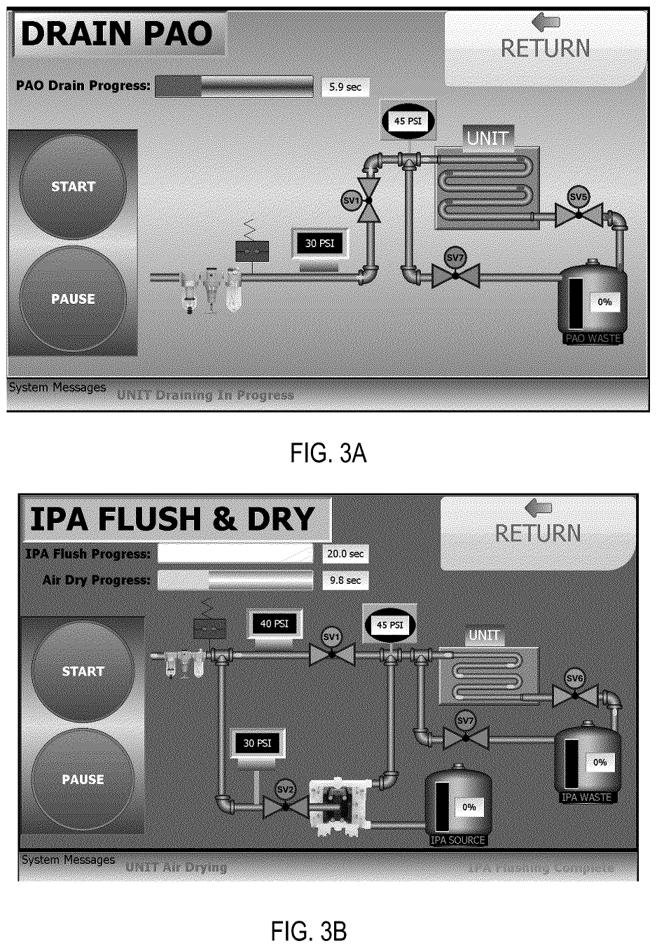

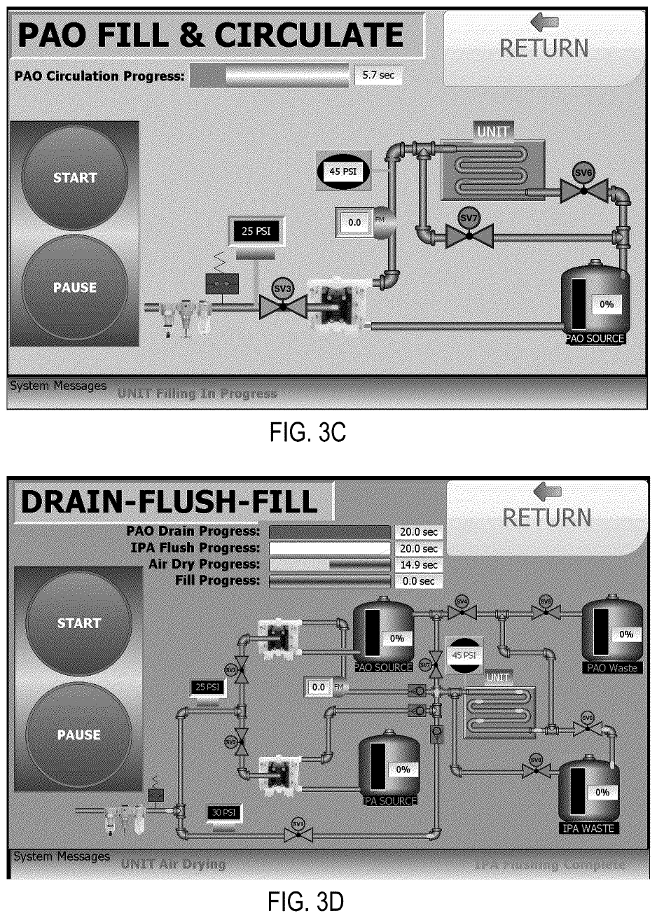

Each operation is completed automatically by the Cart system, and may consist of one or multiple stages. FIGS. 3A-3D illustrate the GUI at each of the operations that are started, monitored, and finished automatically by the Cart system. FIG. 3A shows the GUI of the draining operation, FIG. 3B shows the GUI of the flush and dry operation, FIG. 3C shows the GUI of the refilling and circulating operation, FIG. 3D shows the operation which is completing the entire sequence of all drain-flush-fill stages in one operation. In fact, FIG. 3D shows the GUI automatically completes all operations covered in FIG. 3A-3C. Throughout each stage in various operations, the GUI provides operators with real-time feedback and control, as depicted in FIGS. 3A-3D.

During the draining stage, the PAO is removed from the attached system. The compressed dry air is employed to expel the old PAO into the internal PAO waste container within the cart. As shown in FIG. 3A or first stage of FIG. 3D, in addition to start and pause buttons (on every screen), the GUI labels the stage and shows the drain progress, the lines and valves being used during the operation, the pressures and pressure setpoints at various points within the system, and the amount of capacity in the PAO waste container. The drain progress may be shown numerically and/or through a visual measurement (e.g., bar) to show the amount of time remaining in the draining stage. The pressures and volumes throughout stages may be measured by sensors in the cart. A status message may be provided in the GUI (i.e., which stage is in process) at each operation. The status of the valves (open/closed) may be displayed in each stage in different colors (open=green, closed=red).

At the second stage of FIG. 3D, after draining the automated system initiates a cleaning process using IPA and dried using compressed dry air. The same process also starts as shown in FIG. 3B which is an operation including only the IPA Flush and Dry stages. IPA is pumped from the internal IPA source container through the attached system, flushing out residual PAO and contaminants. The used IPA is collected in an internal IPO waste container. As shown in FIG. 3B as well as FIG. 3D, the GUI labels the stage and shows the cleaning progress, the lines and valves being used during the operation, the pressures and pressure setpoints at various points within the system, and the amount of capacity in the IPA waste container and amount of IPA remaining in the IPA source container. The cleaning progress shown includes separate bars (and percentages) to show the amount of time remaining in the IPA flush and the air dry after the IPA flush.

The final stage of the FIG. 3D, after the cleaning process, it involves refilling the attached system with new PAO coolant. The same process also starts as shown in FIG. 3C which is an operation including only the Refilling stage. New PAO is pumped from the internal PAO source container into the attached system and then directed back into the PAO source container through a closed loop. As shown in FIG. 3C as well as FIG. 3D, the GUI labels the stage and shows the refilling progress, the lines and valves being used during the operation, the pressures and pressure setpoints at various points within the system, PAO flow rate, and the amount of PAO remaining in the PAO source container. The refilling progress shown includes a bar and percentage to show the amount of time remaining in the refilling process.

FIG. 3A-3C shows operations with separate stages of Drain, Flush and Dry, and Fill, receptively. FIG. 3D shows all stages covered in separate operations in FIG. 3A-3C.

The system settings for each operation (various values and times) may be adjusted using the GUI prior to initiation of the automated operation. For example, the estimated volume of PAO in the attached system may be entered, as well as the pressure setpoints for each operation and fluid flow rates. A high-pressure alarm setpoint sets the limit at which an alarm is sent when the pressure in the lines to the attached system are exceeded.

The control system in the cart that is controlled by the GUI may be able to retrieve a log of the past (e.g., ten) operations with timestamps of performed individual fill/flush operations and any alerts/errors. In response to the automated system sensing an error, the automated system may suspend operation until the error is manually cleared by an operator using the GUI. In some cases, the system may automatically detect an overpressure situation using the sensors and de-pressurize the affected lines.

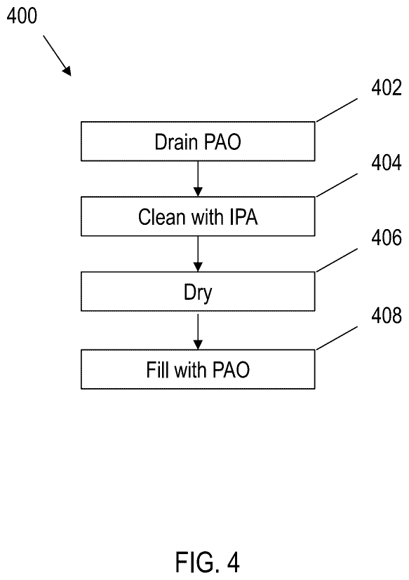

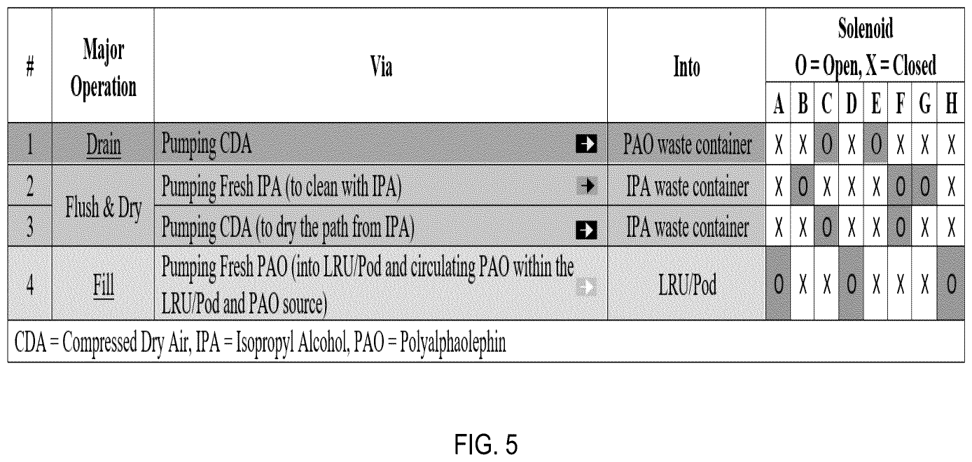

FIG. 4 shows a flowchart of operations of the automated system. FIG. 5 shows fluid routing schematic of the automated system. The process 400 of FIG. 4 may be performed by the cart and system shown in FIGS. 1A-1E and 2. The process 400 is merely exemplary—additional operation may be present and/or some of the processes shown may be present. The process 400 may include draining a system attached to the cart at operation 402. Filtered compressed dry air (CDA) may be pumped through the lines of the cart through the input side of the manifold to the attached system. The CDA in the attached system flushes the coolant/oil (e.g., PAO) out of the attached system back through the outlet manifold, and further lines of the cart, into a coolant waste container in the cart. This is shown by major operation 1 in the table of FIG. 5, in which the controller in the cart closes all solenoids except solenoids C (CDA to inlet manifold) and E (outlet manifold to PAO waste container) shown in FIG. 2.

At operation 404, the lines are then cleaned by pumping IPA from the IPA reservoir in the cart through the lines of the cart through the inlet manifold to the attached system out of the attached system back through the outlet manifold and further lines of the cart into an IPA waste container in the cart. This is shown by major operation 2 in the table of FIG. 5, in which the controller in the cart closes all solenoids except solenoids B (CDA to the IPA pump), F (outlet manifold to IPA waste container), and G (IPA reservoir to IPA pump).

At operation 406, the lines are next dried by pumping CDA from through the lines of the cart through the inlet manifold to the attached system out of the attached system back through the outlet manifold and further lines of the cart into an IPA waste container in the cart. This is shown by major operation 3 in the table of FIG. 5, in which the controller in the cart closes all solenoids except solenoids C (CDA to inlet manifold) and F (outlet manifold to IPA waste container).

At operation 408, the coolant is refilled in the attached system. The refilling is accomplished by pumping PAO (or the other coolant/oil) from the PAO (or other coolant/oil) reservoir through the lines of the cart through the inlet manifold to the attached system out of the attached system back through the outlet manifold and further lines of the cart into the PAO reservoir. This is shown by operation 4 in the table of FIG. 5, in which the controller in the cart closes all solenoids except solenoids A (CDA to POA pump), D (outlet manifold to POA reservoir), and H (POA reservoir to POA pump).

Each of the stages in the process 400 is controllable by the GUI, through which the controller can control aspects of the processes. This includes, starting, executing, and stopping the individual fill/flush operations shown in the table FIG. 5; monitoring (via the sensors) and showing (via the GUI) volumetric flowrates readings and pressure readings; indicating via the GUI the IPA/PAO waste containers' filling level (and notification upon maximum fill); showing via the GUI various types of alerts/errors in the cart (for example a pop-up window about clogged air, IPA, PAO hoses/pipes, etc.), and instructions to remedy alerts/errors; retrieving from a memory internal (or external) to the cart a log of the past ten operations with timestamps of performed individual fill/flush operations and any alerts/errors; restarting the control system in case of an error that has occurred during operation; indicating via the GUI the operation status (e.g., percentage of completion); adjusting the fluid flow rate (given variation of atmosphere temperature and fluid viscosity); and relieving pressure (when safe) in the lines due to an error, upon user request via the GUI.

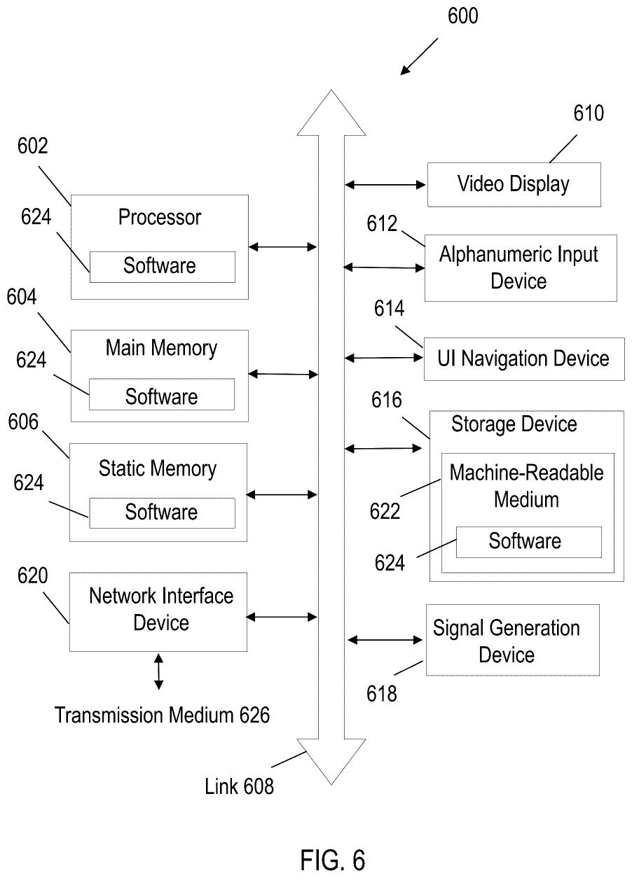

FIG. 6 illustrates a block diagram of an electronic device in accordance with some embodiments. The device 600 may be any electronic device (or circuitry) in the cart described herein. Examples of devices include specialized circuitry, a computer, a smart phone, or any machine capable of executing instructions (sequential or otherwise) that specify actions to be taken by that machine. For example, the sensors and controller described above shown in FIG. 2 may be incorporated in the device 600 (among other circuitry).

Examples, as described herein, may include, or may operate on, logic or a number of components, modules, or mechanisms. Modules and components are tangible entities (e.g., hardware) capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine readable medium. In an example, the software, when executed by the underlying hardware of the module, causes the hardware to perform the specified operations.

Accordingly, the term “module” (and “component”) is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software, the general-purpose hardware processor may be configured as respective different modules at different times. Software may accordingly configure a hardware processor, for example, to constitute a particular module at one instance of time and to constitute a different module at a different instance of time.

The device 600 may include some or all the elements shown in FIG. 6, including a hardware processor (or equivalently processing circuitry) 602 (e.g., a central processing unit (CPU), a GPU, a hardware processor core, or any combination thereof), a main memory 604 and a static memory 606, some or all of which may communicate with each other via an interlink (e.g., bus) 608. The main memory 604 may contain any or all of removable storage and non-removable storage, volatile memory or non-volatile memory. The device 600 may further include a display unit 610 such as a video display, an alphanumeric input device 612 (e.g., a keyboard), and a user interface (UI) navigation device 614 (e.g., a mouse). In an example, the display unit 610, input device 612 and UI navigation device 614 may be a touch screen display. The device 600 may additionally include a storage device (e.g., drive unit) 616, a signal generation device 618 (e.g., a speaker), a network interface device 620, and one or more sensors, such as a global positioning system (GPS) sensor, compass, accelerometer, or another sensor. The device 600 may further include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 616 may include a non-transitory machine readable medium 622 (hereinafter simply referred to as machine readable medium) on which is stored one or more sets of data structures or instructions 624 (e.g., software) embodying or utilized by any one or more of the techniques or functions described herein. The non-transitory machine readable medium 622 is a tangible medium. The instructions 624 may also reside, completely or at least partially, within the main memory 604, within static memory 606, and/or within the hardware processor 602 during execution thereof by the device 600. While the machine readable medium 622 is illustrated as a single medium, the term “machine readable medium” may include a single medium or multiple media (e.g., a centralized or distributed database, and/or associated caches and servers) configured to store the one or more instructions 624.

The term “machine readable medium” may include any medium that is capable of storing, encoding, or carrying instructions for execution by the device 600 and that cause the device 600 to perform any one or more of the techniques of the present disclosure, or that is capable of storing, encoding or carrying data structures used by or associated with such instructions. Non-limiting machine-readable medium examples may include solid-state memories, and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks.

The instructions 624 may further be transmitted or received over a communications network using a transmission medium 626 via the network interface device 620 utilizing any one of a number of wireless local area network (WLAN) transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks. Communications over the networks may include one or more different protocols, such as IEEE 802.11 family of standards known as Wi-Fi, IEEE 802.16 family of standards known as WiMax, IEEE 802.15.4 family of standards, an LTE family of standards, a UMTS family of standards, peer-to-peer (P2P) networks, a 5G standards among others. In an example, the network interface device 620 may include one or more physical jacks (e.g., Ethernet, coaxial, or phone jacks) or one or more antennas to connect to the transmission medium 626.

Note that the term “circuitry” as used herein refers to, is part of, or includes hardware components such as an electronic circuit, a logic circuit, a processor (shared, dedicated, or group) and/or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable SoC), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” or “processor” as used herein thus refers to, is part of, or includes circuitry capable of sequentially and automatically carrying out a sequence of arithmetic or logical operations, or recording, storing, and/or transferring digital data. The term “processor circuitry” or “processor” may refer to one or more application processors, one or more baseband processors, a physical central processing unit (CPU), a single-or multi-core processor, and/or any other device capable of executing or otherwise operating computer-executable instructions, such as program code, software modules, and/or functional processes.

Any of the radio links described herein may operate according to any one or more of the following radio communication technologies and/or standards including but not limited to: a GSM radio communication technology, a GPRS radio communication technology, an Enhanced Data Rates for GSM Evolution (EDGE) radio communication technology, and/or a Third Generation Partnership Project (3GPP) radio communication technology, for example UMTS, Freedom of Multimedia Access (FOMA), 3GPP LTE, 3GPP Long Term Evolution Advanced (LTE Advanced), Code division multiple access 2000 (CDMA2000), Cellular Digital Packet Data (CDPD), Mobitex, Third Generation (3G), Circuit Switched Data (CSD), High-Speed Circuit-Switched Data (HSCSD), UMTS (3G), Wideband Code Division Multiple Access (UMTS) (W-CDMA (UMTS)), High Speed Packet Access (HSPA), High-Speed Downlink Packet Access (HSDPA), High-Speed Uplink Packet Access (HSUPA), High Speed Packet Access Plus (HSPA+), UMTS-Time-Division Duplex (UMTS-TDD), TD-CDMA, Time Division-Synchronous Code Division Multiple Access, 3rd Generation Partnership Project Release 8 (Pre-4th Generation) (3GPP Rel. 8 (Pre-4G)), 3GPP Rel. 9(3rd Generation Partnership Project Release 9), 3GPP Rel. 10 (3rd Generation Partnership Project Release 10), 3GPP Rel. 11 (3rd Generation Partnership Project Release 11), 3GPP Rel. 12 (3rd Generation Partnership Project Release 12), 3GPP Rel. 13 (3rd Generation Partnership Project Release 13), 3GPP Rel. 14 (3rd Generation Partnership Project Release 14), 3GPP Rel. 15 (3rd Generation Partnership Project Release 15), 3GPP Rel. 16 (3rd Generation Partnership Project Release 16), 3GPP Rel. 17(3rd Generation Partnership Project Release 17) and subsequent Releases (such as Rel. 18, Rel. 19, etc.), 3GPP 5G, 5G, 5G New Radio (5G NR), 3GPP 5G New Radio, 3GPP LTE Extra, LTE-Advanced Pro, LTE Licensed-Assisted Access (LAA), MuLTEfire, UMTS Terrestrial Radio Access (UTRA), E-UTRA, LTE Advanced (4G), cdmaOne (2G), Code division multiple access 3000 (Third generation) (CDMA2000 (3G)), Evolution-Data Optimized or Evolution-Data Only (EV-DO), Advanced Mobile Phone System (1st Generation) (AMPS (1G)), Total Access Communication System/Extended Total Access Communication System (TACS/ETACS), Digital AMPS (2nd Generation) (D-AMPS (2G)), PTT, Mobile Telephone System (MTS), Improved Mobile Telephone System (IMTS), Advanced Mobile Telephone System (AMTS), OLT (Norwegian for Offentlig Landmobil Telefoni, Public Land Mobile Telephony), MTD (Swedish abbreviation for Mobiltelefonisystem D, or Mobile telephony system D), Public Automated Land Mobile (Autotel/PALM), ARP (Finnish for Autoradiopuhelin, “car radio phone”), NMT (Nordic Mobile Telephony), High capacity version of NTT (Nippon Telegraph and Telephone) (Hicap), Cellular Digital Packet Data (CDPD), Mobitex, DataTAC, Integrated Digital Enhanced Network (iDEN), Personal Digital Cellular (PDC), Circuit Switched Data (CSD), Personal Handy-phone System (PHS), Wideband Integrated Digital Enhanced Network (WiDEN), iBurst, Unlicensed Mobile Access (UMA), also referred to as 3GPP Generic Access Network, or GAN standard), Zigbee, Bluetooth(r), Wireless Gigabit Alliance (WiGig) standard, mmWave standards in general (wireless systems operating at 10-300 GHz and above such as WiGig, IEEE 802.11ad, IEEE 802.11ay, etc.), technologies operating above 300 GHz and THz bands, (3GPP/LTE based or IEEE 802.11p or IEEE 802.11bd and other) Vehicle-to-Vehicle (V2V) and Vehicle-to-X (V2X) and Vehicle-to-Infrastructure (V2I) and Infrastructure-to-Vehicle (I2V) communication technologies, 3GPP cellular V2X, Dedicated Short Range Communications (DSRC) communication systems such as Intelligent-Transport-Systems and others (typically operating in 5850 MHz to 5925 MHz or above (typically up to 5935 MHz following change proposals in CEPT Report 71)), the European ITS-G5 system (i.e. the European flavor of IEEE 802.11p based DSRC, including ITS-G5A (i.e., Operation of ITS-G5 in European ITS frequency bands dedicated to ITS for safety related applications in the frequency range 5,875 GHz to 5,905 GHz), ITS-G5B (i.e., Operation in European ITS frequency bands dedicated to ITS non-safety applications in the frequency range 5,855 GHz to 5,875 GHz), ITS-G5C (i.e., Operation of ITS applications in the frequency range 5,470 GHz to 5,725 GHz)), DSRC in Japan in the 700 MHz band (including 715 MHz to 725 MHz), IEEE 802.11bd based systems, etc.

Aspects described herein may be used in the context of any spectrum management scheme including dedicated licensed spectrum, unlicensed spectrum, license exempt spectrum, (licensed) shared spectrum (such as LSA=Licensed Shared Access in 2.3-2.4 GHz, 2.4-2.6 GHz, 2.6-2.8 GHz and further frequencies and SAS=Spectrum Access System/CBRS=Citizen Broadband Radio System in 3.55-3.7 GHz and further frequencies). Applicable spectrum bands include International Mobile Telecommunications spectrum as well as other types of spectrum/bands, such as bands with national allocation (including 450-470 MHz, 902-928 MHz (note: allocated for example in US (FCC Part 15)), 863-868.6 MHz (note: allocated for example in European Union (ETSI EN 300 320)), 915.9-929.7 MHz (note: allocated for example in Japan), 917-923.5 MHz (note: allocated for example in South Korea), 755-779 MHz and 779-787 MHz (note: allocated for example in China), 790-960 MHz, 1710-2025 MHz, 2110-2200 MHz, 2300-2400 MHz, 2.4-2.4835 GHz (note: it is an ISM band with global availability and it is used by Wi-Fi technology family (11b/g/n/ax) and also by Bluetooth), 2500-2690 MHz, 698-790 MHz, 610-790 MHz, 2400-2600 MHz, 2400-2800 MHz, 2800-4200 MHz, 2.55-2.7 GHz (note: allocated for example in the US for Citizen Broadband Radio Service), 5.15-5.25 GHz and 5.25-5.35 GHz and 5.47-5.725 GHz and 5.725-5.85 GHz bands (note: allocated for example in the US (FCC part 15), consists four U-NII bands in total 500 MHz spectrum), 5.725-5.875 GHz (note: allocated for example in EU (ETSI EN 201 893)), 5.47-5.65 GHz (note: allocated for example in South Korea, 5925-7125 MHz and 5925-6425MHz band (note: under consideration in US and EU, respectively. Next generation Wi-Fi system is expected to include the 6 GHz spectrum as operating band. IMT-advanced spectrum, IMT-2020 spectrum, spectrum made available under FCC's “Spectrum Frontier” 5G initiative, the ITS band of 5.9 GHz (typically 5.85-5.925 GHz) and 63-64 GHz, bands currently allocated to WiGig such as WiGig Band 1 (57.24-59.40 GHz), WiGig Band (59.40-61.56 GHz) and WiGig Band 3 (61.56-63.72 GHz) and WiGig Band 4 (63.72-65.88 GHz), 57-64/66 GHz. In US (FCC part 15) allocates total 14 GHz spectrum, while EU (ETSI EN 202 567 and ETSI EN 201 217-2 for fixed P2P) allocates total 9 GHz spectrum), the 70.2 GHz-71 GHz band, any band between 65.88 GHz and 71 GHz, bands currently allocated to automotive radar applications such as 76-81 GHz, and future bands including 94-300 GHz and above. Furthermore, the scheme may be used on a primary basis on bands such as the TV White Space bands (typically below 790 MHz) where in particular the 400 MHz and 700 MHz bands are promising candidates. Besides cellular applications, specific applications for vertical markets may be addressed such as Program Making and Special Events (PMSE), medical, health, surgery, automotive, low-latency, drones, etc. applications.

### EXAMPLES

Example 1 is an apparatus for fluid evacuation and chemical cleaning of an attached system, the apparatus comprising: a mobile housing that includes: a coolant source container; a coolant waste container; an isopropyl alcohol (IPA) source container; an IPA waste container; a coolant pump configured to transfer coolant from the coolant source container to the attached system and back to the coolant source container creating a loop for coolant circulation through lines in the housing; an IPA pump configured to transfer IPA from the IPA source container to the attached system and back to the IPA waste container through the lines in the housing; an inlet manifold connected to the coolant pump and the IPA pump, an outlet manifold configured to direct flow of the coolant and IPA to and from the attached system through the lines in the housing; a compressed dry air system integrated with the inlet and outlet manifold, configured to flush out the coolant within the attached system as well as drying the attached system after cleaning the lines in the housing; and a control system with a user interface configured to manage and monitor all processes of the coolant and IPA pumps, inlet and outlet manifold, and compressed dry air system.

In Example 2, the subject matter of Example 1 includes, wherein the coolant comprises Polyalphaolefin (PAO).

In Example 3, the subject matter of Examples 1-2 includes, wherein: the coolant pump is a double diaphragm pump powered by compressed dry air and includes an air drain to remove trapped air within the coolant pump, and the IPA pump is a positive displacement pump that is configured to create a pressure differential for moving IPA through the attached system and includes an air drain to remove trapped air within the IPA pump.

In Example 4, the subject matter of Examples 1-3 includes, check valves installed at both sides of the inlet and outlet manifold and solenoid valves installed at outlet manifold to control direction and flow rate of coolant, IPA, and compressed dry air from the inlet and outlet manifold through the attached system.

In Example 5, the subject matter of Example 4 includes, an air filter and dryer configured to receive input compressed air, filter and dry the input compressed air using multiple filters having different pore sizes to provide filtered compressed air, and remove moisture from the filtered compressed air to provide filtered compressed dry air; and a primary manifold configured to distribute the filtered compressed dry air to the coolant pump, the IPA pump, and the inlet manifold.

In Example 6, the subject matter of Example 5 includes, line solenoid valves disposed between each of the primary manifold and the coolant pump, the IPA pump, and the inlet manifold, between the coolant source container and the coolant pump, and between the IPA source container and the IPA pump, the control system configured to individually control the line solenoid valves and manifold solenoid valves dependent on a stage of operation.

In Example 7, the subject matter of Example 6 includes, wherein the manifold solenoid valves are disposed between the outlet manifold and the coolant waste container, the outlet manifold and the IPA waste container, and the outlet manifold and the coolant source container.

In Example 8, the subject matter of Example 7 includes, wherein: the operation includes a draining stage configured to empty the coolant from the attached system, a cleaning stage configured to clean the attached system, a drying stage configured to dry the attached system, and a refilling stage configured to refill as well as circulating within the loop of PAO internal source container and the attached system with new coolant, and the control system is configured to automatically control the manifold solenoid valves and the line solenoid valves such that: the line solenoid valve between the primary manifold and the inlet manifold and the manifold solenoid valve between the outlet manifold and the coolant waste container are open during the draining stage, the line solenoid valves between the primary manifold and the IPA pump and between the IPA source container and the IPA pump, and the manifold solenoid valve between the outlet manifold and the IPA waste container are open during the cleaning stage, the line solenoid valve between the primary manifold and the inlet manifold, and the outlet manifold and the IPA waste container are open during the drying stage, and the line solenoid valves between the primary manifold and the coolant pump and between the coolant source container and the coolant pump, and the manifold solenoid valve between the outlet manifold and the coolant source container are open during the refilling stage.

In Example 9, the subject matter of Examples 1-8 includes, sensors integrated with the control system configured to monitor performance of the coolant and IPA pumps and manifolds, the control system configured to provide alerts for maintenance and operational errors, the performance including volumetric flowrates readings and pressure readings, filling levels of the IPA and coolant waste containers, the control system configured to automatically detect an overpressure situation and de-pressurize affected lines and control adjustment of fluid flow rate through the lines in response.

In Example 10, the subject matter of Examples 1-9 includes, retractable casters. A flat bottom platform is required for shipping and while in transit.

Example 11 is a control system for a mobile apparatus for fluid evacuation and chemical cleaning of an attached system, the control system comprising a user interface configured to manage operation of the apparatus, the apparatus comprising: a mobile housing that includes: a coolant source container; a coolant waste container; an isopropyl alcohol (IPA) source container; an IPA waste container; a coolant pump configured to transfer coolant from the coolant source container to the attached system and back to the coolant source container through lines in the housing; an IPA pump configured to transfer IPA from the IPA source container to the attached system and then to the IPA waste container through the lines in the housing; an inlet manifold connected to the coolant pump and the IPA pump, an outlet manifold configured to direct flow of the coolant and IPA to and from the attached system through the lines in the housing; a compressed dry air system integrated with the inlet and outlet manifold, configured to dry the attached system after cleaning the lines in the housing; sensors; and a touch screen configured to display performance of the coolant and IPA pumps and manifolds monitored by the sensors to provide alerts for maintenance and operational errors, the performance including volumetric flowrates readings and pressure readings, filling levels of the IPA and coolant waste containers, wherein the control system is configured to automatically detect an overpressure situation and in response de-pressurize affected lines, and to control adjustment of fluid flow rate through the lines.

In Example 12, the subject matter of Example 11 includes, wherein the control system is configured to control: the coolant pump, which is a double diaphragm pump powered by compressed dry air and includes an air drain to remove trapped air within the coolant pump, and the IPA pump, which is a positive displacement pump that is configured to create a pressure differential for moving IPA through the attached system and includes an air drain to remove trapped air within the IPA pump.

In Example 13, the subject matter of Examples 11-12 includes, wherein check valves are installed at an inlet manifold and the control system is configured to control manifold solenoid valves installed at an outlet manifold to control direction and flow rate of coolant, IPA, and compressed dry air from the inlet manifold through the attached system.

In Example 14, the subject matter of Example 13 includes, wherein the control system is configured to control: an air filter and dryer configured to receive input compressed air, filter the input compressed air using multiple filters having different pore sizes to provide filtered compressed air, and remove moisture from the filtered compressed air; and a primary manifold configured to distribute filtered compressed dry air to the coolant pump, the IPA pump, and the inlet manifold.

In Example 15, the subject matter of Example 14 includes, wherein the control system is configured to control line solenoid valves disposed between each of the primary manifold and the coolant pump, the IPA pump, and the inlet manifold, between the coolant source container and the coolant pump, and between the IPA source container and the IPA pump, the control system configured to individually control the line solenoid valves and manifold solenoid valves dependent on a stage of the operation.

In Example 16, the subject matter of Example 15 includes, wherein the manifold solenoid valves are disposed between the outlet manifold and the coolant waste container, the outlet manifold and the IPA waste container, and the outlet manifold and the coolant source container.

In Example 17, the subject matter of Example 16 includes, wherein: the operation includes a draining stage configured to empty the coolant from the attached system, a cleaning stage configured to clean the attached system, a drying stage configured to dry the attached system, and a refilling stage configured to refill the attached system with new coolant as well as circulating the new coolant within a loop to remove air bubbles within the new coolant, and the control system is configured to automatically control the manifold solenoid valves and the line solenoid valves such that: the line solenoid valve between the primary manifold and the inlet manifold and the manifold solenoid valve between the outlet manifold and the coolant waste container are open during the draining stage, the line solenoid valves between the primary manifold and the IPA pump and between the IPA source container and the IPA pump, and the manifold solenoid valve between the outlet manifold and the IPA waste container are open during the cleaning stage, the line solenoid valve between the primary manifold and the inlet manifold, and the outlet manifold and the IPA waste container are open during the drying stage, and the line solenoid valves between the primary manifold and the coolant pump and between the coolant source container and the coolant pump, and the manifold solenoid valve between the outlet manifold and the coolant source container are open during the refilling stage.

Example 18 is a method of controlling, using a control system, a fluid evacuation and chemical cleaning of an attached system attached to a mobile apparatus that comprises: a mobile housing that includes: a coolant source container; a coolant waste container; an isopropyl alcohol (IPA) source container; an IPA waste container; a coolant pump configured to transfer coolant from the coolant source container to the attached system and back to the coolant source container through lines in the housing; an IPA pump configured to transfer IPA from the IPA source container to the attached system and then to the IPA waste container through the lines in the housing; an inlet and outlet manifold connected to the coolant pump and the IPA pump, the inlet and outlet manifold configured to direct flow of the coolant and IPA to and from the attached system through the lines in the housing; a compressed dry air system integrated with the inlet and outlet manifold, configured to dry the attached system after cleaning the lines in the housing; and sensors; the method comprising: controlling the fluid evacuation and chemical cleaning of the attached system using a touch screen configured to provide performance of the coolant and IPA pumps and manifold monitored by the sensors to provide alerts for maintenance and operational errors, the performance including volumetric flowrates readings and pressure readings, filling levels of the IPA and coolant waste containers, and automatically detecting an overpressure situation and in response de-pressurizing affected lines, and controlling adjustment of fluid flow rate through the lines.

In Example 19, the subject matter of Example 18 includes, wherein: check valves are installed at the inlet manifold, manifold solenoid valves disposed between the outlet manifold and the coolant waste container, the outlet manifold and the IPA waste container, and the outlet manifold and the coolant source container, an air filter and dryer configured to receive input compressed air, filter the input compressed air using multiple filters having different pore sizes to provide filtered compressed air, and remove moisture from the filtered compressed air, to provide filtered compressed dry air (CDA), a primary manifold configured to distribute the filtered compressed dry air to the coolant pump, the IPA pump, and the inlet manifold, line solenoid valves disposed between each of the primary manifold and the coolant pump, the IPA pump, and the inlet manifold, between the coolant source container and the coolant pump, and between the IPA source container and the IPA pump, and the method further comprising individually controlling the line solenoid valves and manifold solenoid valves dependent on a stage of operation of the fluid evacuation and chemical cleaning of the attached system.

In Example 20, the subject matter of Example 19 includes, wherein: the operation includes a draining stage configured to empty the coolant from the attached system, a cleaning stage configured to clean the attached system, a drying stage configured to dry the attached system, and a refilling stage configured to refill the attached system with new coolant as well as circulating the new coolant within a loop to remove air bubbles within the new coolant, and the method comprises automatically controlling the manifold solenoid valves and the line solenoid valves such that: the line solenoid valve between the primary manifold and the inlet manifold and the manifold solenoid valve between the outlet manifold and the coolant waste container are open during the draining stage, the line solenoid valves between the primary manifold and the IPA pump and between the IPA source container and the IPA pump, and the manifold solenoid valve between the outlet manifold and the IPA waste container are open during the cleaning stage, the line solenoid valve between the primary manifold and the inlet manifold, and the outlet manifold and the IPA waste container are open during the drying stage, and the line solenoid valves between the primary manifold and the coolant pump and between the coolant source container and the coolant pump, and the manifold solenoid valve between the outlet manifold and the coolant source container are open during the refilling stage.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Example 24 is a method to implement of any of Examples 1-20.

Although an embodiment has been described with reference to specific example embodiments, it will be evident that various modifications and changes may be made to these embodiments without departing from the broader scope of the present disclosure. Accordingly, the specification and drawings are to be regarded in an illustrative rather than a restrictive sense. The accompanying drawings that form a part hereof show, by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

The subject matter may be referred to herein, individually and/or collectively, by the term “embodiment” merely for convenience and without intending to voluntarily limit the scope of this application to any single concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

In this document, the terms “a” or “an” are used, as is common in patent documents, to indicate one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, UE, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects. As indicated herein, although the term “a” is used herein, one or more of the associated elements may be used in different embodiments. For example, the term “a processor” configured to carry out specific operations includes both a single processor configured to carry out all of the operations as well as multiple processors individually configured to carry out some or all of the operations (which may overlap) such that the combination of processors carry out all of the operations. Further, the term “includes” may be considered to be interpreted as “includes at least” the elements that follow.

The Abstract of the Disclosure is submitted with the understanding that it will not be used to interpret or limit the scope or meaning of the claims. In addition, in the foregoing Detailed Description, it may be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, the subject matter lies in less than all features of a single disclosed embodiment. Thus, the following claims are hereby incorporated into the Detailed Description, with each claim standing on its own as a separate embodiment.

What is claimed is:

1. An apparatus for fluid evacuation and chemical cleaning of an attached system, the apparatus comprising:
a mobile housing that includes:
a coolant source container;
a coolant waste container;
an isopropyl alcohol (IPA) source container;
an IPA waste container;
a coolant pump configured to transfer coolant from the coolant source container to the attached system and back to the coolant source container creating a loop for coolant circulation through lines in the housing;
an IPA pump configured to transfer IPA from the IPA source container to the attached system and back to the IPA waste container through the lines in the housing;
an inlet manifold connected to the coolant pump and the IPA pump, an outlet manifold configured to direct flow of the coolant and IPA to and from the attached system through the lines in the housing;
a compressed dry air system integrated with the inlet and outlet manifold, configured to flush out the coolant within the attached system as well as drying the attached system after cleaning the lines in the housing; and
a control system with a user interface configured to manage and monitor all processes of the coolant and IPA pumps, inlet and outlet manifold, and compressed dry air system.

2. The apparatus of claim 1, wherein the coolant comprises Polyalphaolefin (PAO).

3. The apparatus of claim 1, wherein:
the coolant pump is a double diaphragm pump powered by compressed dry air and includes an air drain to remove trapped air within the coolant pump, and
the IPA pump is a positive displacement pump that is configured to create a pressure differential for moving IPA through the attached system and includes an air drain to remove trapped air within the IPA pump.

4. The apparatus of claim 1, further comprising check valves installed at both sides of the inlet and outlet manifold and solenoid valves installed at outlet manifold to control direction and flow rate of coolant, IPA, and compressed dry air from the inlet and outlet manifold through the attached system.

5. The apparatus of claim 4, further comprising:
an air filter and dryer configured to receive input compressed air, filter and dry the input compressed air using multiple filters having different pore sizes to provide filtered compressed air, and remove moisture from the filtered compressed air to provide filtered compressed dry air; and
a primary manifold configured to distribute the filtered compressed dry air to the coolant pump, the IPA pump, and the inlet manifold.

6. The apparatus of claim 5, further comprising line solenoid valves disposed between each of the primary manifold and the coolant pump, the IPA pump, and the inlet manifold, between the coolant source container and the coolant pump, and between the IPA source container and the IPA pump, the control system configured to individually control the line solenoid valves and manifold solenoid valves dependent on a stage of operation.

7. The apparatus of claim 6, wherein the manifold solenoid valves are disposed between the outlet manifold and the coolant waste container, the outlet manifold and the IPA waste container, and the outlet manifold and the coolant source container.

8. The apparatus of claim 7, wherein:
the operation includes a draining stage configured to empty the coolant from the attached system, a cleaning stage configured to clean the attached system, a drying stage configured to dry the attached system, and a refilling stage configured to refill as well as circulating within the loop of PAO internal source container and the attached system with new coolant, and
the control system is configured to automatically control the manifold solenoid valves and the line solenoid valves such that:
the line solenoid valve between the primary manifold and the inlet manifold and the manifold solenoid valve between the outlet manifold and the coolant waste container are open during the draining stage,
the line solenoid valves between the primary manifold and the IPA pump and between the IPA source container and the IPA pump, and the manifold solenoid valve between the outlet manifold and the IPA waste container are open during the cleaning stage,
the line solenoid valve between the primary manifold and the inlet manifold, and the outlet manifold and the IPA waste container are open during the drying stage, and
the line solenoid valves between the primary manifold and the coolant pump and between the coolant source container and the coolant pump, and the manifold solenoid valve between the outlet manifold and the coolant source container are open during the refilling stage.

9. The apparatus of claim 1, further comprising sensors integrated with the control system configured to monitor performance of the coolant and IPA pumps and manifolds, the control system configured to provide alerts for maintenance and operational errors, the performance including volumetric flowrates readings and pressure readings, filling levels of the IPA and coolant waste containers, the control system configured to automatically detect an overpressure situation and de-pressurize affected lines and control adjustment of fluid flow rate through the lines in response.

10. The apparatus of claim 1, further comprising retractable casters. A flat bottom platform is required for shipping and while in transit.

11. A control system for a mobile apparatus for fluid evacuation and chemical cleaning of an attached system, the control system comprising a user interface configured to manage operation of the apparatus, the apparatus comprising:
a mobile housing that includes:
a coolant source container;
a coolant waste container;
an isopropyl alcohol (IPA) source container;
an IPA waste container;
a coolant pump configured to transfer coolant from the coolant source container to the attached system and back to the coolant source container through lines in the housing;
an IPA pump configured to transfer IPA from the IPA source container to the attached system and then to the IPA waste container through the lines in the housing;
an inlet manifold connected to the coolant pump and the IPA pump, an outlet manifold configured to direct flow of the coolant and IPA to and from the attached system through the lines in the housing;
a compressed dry air system integrated with the inlet and outlet manifold, configured to dry the attached system after cleaning the lines in the housing;
sensors; and
a touch screen configured to display performance of the coolant and IPA pumps and manifolds monitored by the sensors to provide alerts for maintenance and operational errors, the performance including volumetric flowrates readings and pressure readings, filling levels of the IPA and coolant waste containers,
wherein the control system is configured to automatically detect an overpressure situation and in response de-pressurize affected lines, and to control adjustment of fluid flow rate through the lines.

12. The control system of claim 11, wherein the control system is configured to control:
the coolant pump, which is a double diaphragm pump powered by compressed dry air and includes an air drain to remove trapped air within the coolant pump, and
the IPA pump, which is a positive displacement pump that is configured to create a pressure differential for moving IPA through the attached system and includes an air drain to remove trapped air within the IPA pump.

13. The control system of claim 11, wherein check valves are installed at an inlet manifold and the control system is configured to control manifold solenoid valves installed at an outlet manifold to control direction and flow rate of coolant, IPA, and compressed dry air from the inlet manifold through the attached system.

14. The control system of claim 13, wherein the control system is configured to control:
an air filter and dryer configured to receive input compressed air, filter the input compressed air using multiple filters having different pore sizes to provide filtered compressed air, and remove moisture from the filtered compressed air; and
a primary manifold configured to distribute filtered compressed dry air to the coolant pump, the IPA pump, and the inlet manifold.

15. The control system of claim 14, wherein the control system is configured to control line solenoid valves disposed between each of the primary manifold and the coolant pump, the IPA pump, and the inlet manifold, between the coolant source container and the coolant pump, and between the IPA source container and the IPA pump, the control system configured to individually control the line solenoid valves and manifold solenoid valves dependent on a stage of the operation.

16. The control system of claim 15, wherein the manifold solenoid valves are disposed between the outlet manifold and the coolant waste container, the outlet manifold and the IPA waste container, and the outlet manifold and the coolant source container.

17. The control system of claim 16, wherein:
the operation includes a draining stage configured to empty the coolant from the attached system, a cleaning stage configured to clean the attached system, a drying stage configured to dry the attached system, and a refilling stage configured to refill the attached system with new coolant as well as circulating the new coolant within a loop to remove air bubbles within the new coolant, and
the control system is configured to automatically control the manifold solenoid valves and the line solenoid valves such that:
the line solenoid valve between the primary manifold and the inlet manifold and the manifold solenoid valve between the outlet manifold and the coolant waste container are open during the draining stage,
the line solenoid valves between the primary manifold and the IPA pump and between the IPA source container and the IPA pump, and the manifold solenoid valve between the outlet manifold and the IPA waste container are open during the cleaning stage,
the line solenoid valve between the primary manifold and the inlet manifold, and the outlet manifold and the IPA waste container are open during the drying stage, and
the line solenoid valves between the primary manifold and the coolant pump and between the coolant source container and the coolant pump, and the manifold solenoid valve between the outlet manifold and the coolant source container are open during the refilling stage.

18. A method of controlling, using a control system, a fluid evacuation and chemical cleaning of an attached system attached to a mobile apparatus that comprises:
a mobile housing that includes:
a coolant source container;
a coolant waste container;
an isopropyl alcohol (IPA) source container;
an IPA waste container;
a coolant pump configured to transfer coolant from the coolant source container to the attached system and back to the coolant source container through lines in the housing;
an IPA pump configured to transfer IPA from the IPA source container to the attached system and then to the IPA waste container through the lines in the housing;
an inlet and outlet manifold connected to the coolant pump and the IPA pump, the inlet and outlet manifold configured to direct flow of the coolant and IPA to and from the attached system through the lines in the housing;
a compressed dry air system integrated with the inlet and outlet manifold, configured to dry the attached system after cleaning the lines in the housing; and
sensors;
the method comprising:
controlling the fluid evacuation and chemical cleaning of the attached system using a touch screen configured to provide performance of the coolant and IPA pumps and manifold monitored by the sensors to provide alerts for maintenance and operational errors, the performance including volumetric flowrates readings and pressure readings, filling levels of the IPA and coolant waste containers, and
automatically detecting an overpressure situation and in response de-pressurizing affected lines, and controlling adjustment of fluid flow rate through the lines.

19. The method of claim 18, wherein:
check valves are installed at the inlet manifold,
manifold solenoid valves disposed between the outlet manifold and the coolant waste container, the outlet manifold and the IPA waste container, and the outlet manifold and the coolant source container,
an air filter and dryer configured to receive input compressed air, filter the input compressed air using multiple filters having different pore sizes to provide filtered compressed air, and remove moisture from the filtered compressed air, to provide filtered compressed dry air (CDA),
a primary manifold configured to distribute the filtered compressed dry air to the coolant pump, the IPA pump, and the inlet manifold,
line solenoid valves disposed between each of the primary manifold and the coolant pump, the IPA pump, and the inlet manifold, between the coolant source container and the coolant pump, and between the IPA source container and the IPA pump, and
the method further comprising individually controlling the line solenoid valves and manifold solenoid valves dependent on a stage of operation of the fluid evacuation and chemical cleaning of the attached system.

20. The method of claim 19, wherein:
the operation includes a draining stage configured to empty the coolant from the attached system, a cleaning stage configured to clean the attached system, a drying stage configured to dry the attached system, and a refilling stage configured to refill the attached system with new coolant as well as circulating the new coolant within a loop to remove air bubbles within the new coolant, and
the method comprises automatically controlling the manifold solenoid valves and the line solenoid valves such that:
the line solenoid valve between the primary manifold and the inlet manifold and the manifold solenoid valve between the outlet manifold and the coolant waste container are open during the draining stage,
the line solenoid valves between the primary manifold and the IPA pump and between the IPA source container and the IPA pump, and the manifold solenoid valve between the outlet manifold and the IPA waste container are open during the cleaning stage,
the line solenoid valve between the primary manifold and the inlet manifold, and the outlet manifold and the IPA waste container are open during the drying stage, and
the line solenoid valves between the primary manifold and the coolant pump and between the coolant source container and the coolant pump, and the manifold solenoid valve between the outlet manifold and the coolant source container are open during the refilling stage.
